(19) United States
(12) Patent Application Publication
(10) Pub. No.: US 2010/0102393 A1
(43) Pub. Date: Apr. 29, 2010

(54) METAL GATE TRANSISTORS

(75) Inventors: James Yong Meng LEE, Singapore (SG); Jin-Ping HAN, Fishkill, NY (US); Voon-Yew THEAN, Fishkill, NY (US)

Correspondence Address: HORIZON IP PTE LTD, 7500A Beach Road, #04-306/308 The Plaza, SINGAPORE 199591, SG

(73) Assignees: CHARTERED SEMICONDUCTOR MANUFACTURING, LTD., Singapore (SG); INFINEON TECHNOLOGIES NORTH AMERICA CORP., Milpitas, CA (US); FREESCALE SEMICONDUCTOR INC., Austin, TX (US)

(21) Appl. No.: 12/260,095

(22) Filed: Oct. 29, 2008

(51) Int. Cl. H01L 27/092; H01L 21/4763

(52) U.S. Cl. 257/369; 438/585; 257/E27.062

(57) ABSTRACT

An integrated circuit that includes a substrate having first and second active regions is disclosed. A first transistor of a first type and a second transistor of a second type are disposed in the first and second active regions respectively. Each transistor includes a gate stack having a metal gate electrode over a gate dielectric layer. First and second gate threshold voltage adjusting (GTVA) layers contacting first and second gate dielectric layer of the first and second transistors are provided. The first GTVA layer tunes a gate threshold voltage of the first transistor. A channel of the second transistor includes dopants to tune the gate threshold voltage of the second transistor.

### BACKGROUND

The fabrication of integrated circuits (ICs) involves the formation of features on a substrate that make up circuit components, such as transistors, resistors and capacitors. The devices are interconnected, enabling the IC to perform the desired functions. A transistor includes a gate and source/drain diffusion regions adjacent thereto. The gate includes a gate electrode over a gate dielectric. Conventional transistors use polysilicon as the gate electrode and silicon oxide as the gate dielectric. An IC typically comprises both p-type and n-type transistors, forming complementary metal oxide semiconductor (CMOS) ICs.

With the continued scaling of ground rules, for example, below 100 nm, metal gates and high-k dielectrics have been proposed to meet performance requirements. However, the use of metal gates requires complex processing in order for p-type and n-type transistors to have symmetrical or right threshold voltages.

From the foregoing discussion, it is desirable to provide tuned or symmetrical threshold voltages for both p-type and n-type transistors in ICs.

### SUMMARY

Embodiments generally relate to integrated circuit (IC) and method of forming an (IC). In one embodiment, an IC that includes a substrate having a first and a second active region is presented. The IC comprises a first transistor of a first type and a second transistor of a second type in the first and second active regions respectively. First and second gate threshold voltage adjusting (GTVA) layers contacting first and second gate dielectric layers of the first and second transistors are provided. The first GTVA layer tunes a gate threshold voltage of the first transistor. A channel of the second transistor includes dopants to tune the gate threshold voltage of the second transistor.

In another embodiment, a method of forming an IC is disclosed. The method includes providing a substrate prepared with first and second active regions, wherein a channel of the second active region comprises a doped channel region. A first transistor of a first type is formed in the first active region. A second transistor of a second type is formed in the second active region. First and second transistors include a gate threshold voltage adjusting (GTVA) layer adjacent to first and second gate dielectric layers of the first and second transistors. The GTVA layer tunes a gate threshold voltage of the first transistor and the second transistor includes a doped channel region to tune a gate threshold voltage of the second transistor.

In yet another embodiment, the second transistor further includes a doped channel region comprising a doped semiconductor layer to tune a gate threshold voltage of the second transistor.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention will now be described hereinafter, by way of example only with reference to the accompanying drawings, in which:

FIG. 1 shows an embodiment of a portion of an IC; and

FIGS. 2a-c show an embodiment of a process for forming an IC.

### DETAILED DESCRIPTION

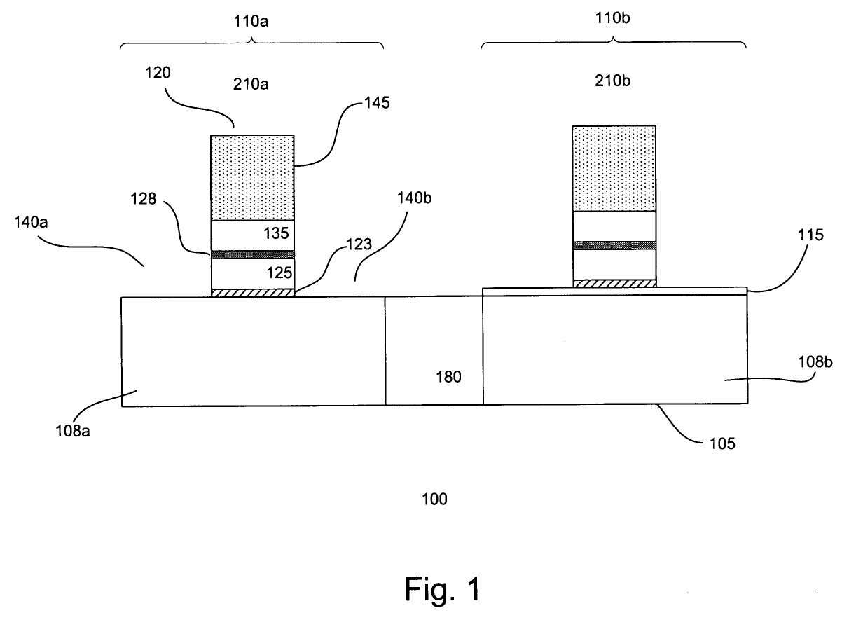

FIG. 1 shows an embodiment of a portion 100 of an IC. The ICs can be any type of IC, for example, dynamic or static random access memories, signal processors, system on chip devices, mixed signal or analog devices such as A/D converters and switched capacitor filters. Other types of ICs are also useful. Such ICs can be incorporated in, for example, communication systems and various types of consumer products.

As shown, the portion includes a substrate 105. The substrate comprises, for example, a silicon substrate. The silicon substrate typically is lightly doped with p-type dopants. Other types of substrates, such as silicon-on-insulator (SOI) are also useful. The substrate is prepared with first and second active regions 110a-b. The active regions comprise heavily doped wells 108a-b with dopants of a first and a second polarity type. In one embodiment, the first active region comprises a doped well of a second polarity type and the second active region comprises a doped well of a first polarity type. The first polarity type can be n-type while the second polarity is p-type. This, for example, results in a p-type doped well in the first active region and a n-type doped well in the second active region. P-type dopants can include boron (B), aluminum or a combination thereof while n-type dopants can include phosphorus (P), arsenic (As), antimony (Sb) or a combination thereof.

Isolating the active regions from each other is an isolation region 180. Isolation regions (not shown) are also provided to isolate the active regions from other active regions. The isolation regions, for example, comprise STI regions. Other types of isolation regions are also useful.

First and second transistors 210a-b are formed in the first and second active regions.

In one embodiment, the first transistor comprises a first or n-type transistor on the p-type doped well and the second transistor comprises a second or p-type transistor on the n-type doped well, forming a CMOS IC. A transistor includes source/drain diffusion regions 140a-b adjacent to a gate stack 120. Sidewall spacers (not shown) can be provided on the gate stacks. P-type transistors have p-type source/drain diffusion regions and n-type transistors have n-type source/drain diffusion regions. Metal silicide contacts (not shown) can be provided on the surface of the diffusion regions and gate stack. The silicide contacts serve to reduce sheet resistance. Various types of metal silicide contacts can be used, such as nickel silicide contacts. Other type of metal silicide contacts can also be useful.

A semiconductor layer 115, in one embodiment, is provided on the surface of the substrate in one of the active regions. The semiconductor layer, for example, is provided on the surface of the substrate in the second active region of the p-type transistor. As shown, the semiconductor layer is elevated above the substrate surface. Providing a semiconductor layer which is coplanar with the substrate is also useful. The semiconductor layer, for example, reduces the effective workfunction of the pFET.

In one embodiment, the semiconductor layer comprises silicon germanium (SiGe). Other types of semiconductor materials may also be useful. In one embodiment, the SiGe is doped with p-type dopants, such as boron (B). The doped semiconductor layer can be doped using in-situ doping process. Doping the semiconductor layer by other doping processes and/or dopants is also useful. The semiconductor layer, in one embodiment, comprises a Ge concentration of about 10-50% with boron concentration of about 1e19-1e21 atoms/cm³. Providing other concentrations of B and Ge may also be useful. The semiconductor layer can be about 20-200 Å thick. Other thicknesses are also useful.

In accordance with one embodiment, the gate stacks of the first and second transistors comprise a metal gate electrode 135 over a high-k gate dielectric 125. The metal gate electrode comprises, for example, titanium nitride (TiN). Other types of metal gate electrodes, such as TaN or TaC, are also useful. The gate electrode comprises a thickness of about 50-500 Å. Providing gate electrodes with other thicknesses is also useful. The high-k gate dielectric, in one embodiment, comprises hafnium oxide (HfO₂). Other types of high-k dielectric materials, such as HfSiOx or HfSiON, are also useful. The high-k gate dielectric is typically about 10-30 Å thick. Other thicknesses are also useful.

To improve adhesion of the high-k gate dielectric to the substrate, a dielectric buffer layer 123 can be provided. The buffer layer, for example, comprises silicon oxide or silicon oxynitride. Typically, the buffer layer is about 8-20 Å. Other types of buffer material or thicknesses are also useful.

The gate stacks include a gate threshold voltage adjusting (GTVA) layer 128. In one embodiment, the GTVA layer is disposed on the high-k dielectric layer. Alternatively, the GTVA layer can be disposed between the high-k dielectric and the buffer layers. Providing GTVA layer at other locations may also be useful. The GTVA layer, in one embodiment, tunes the gate threshold voltage of one of the transistors. In one embodiment, the GTVA layer tunes the gate threshold voltage of the first transistor to the desired level. For example, the GTVA layer tunes the gate threshold voltage of the n-type transistor to the desired level. In one embodiment, the GTVA layer comprises lanthanum oxide (LaO). Other types of materials are also useful. The GTVA layer is about 1-10 Å thick. Other thicknesses are also useful.

Although the GTVA layer tunes the gate threshold voltage of the first transistor, it negatively impacts the gate threshold voltage of the second transistor. In accordance with one embodiment, the channel of the second transistor comprises a doped channel to compensate for the impact of the GTVA layer on the gate threshold voltage of the second transistor. The dopant concentration in the channel should be sufficient to result in the desired gate threshold voltage in the second transistor. In one embodiment, the doped channel is provided by the doped semiconductor layer 115.

A gate electrode buffer layer 145 is provided over the metal gate electrode. The gate electrode buffer layer, in one embodiment, comprises polysilicon. Other types of gate electrode buffer materials, for example amorphous silicon, are also useful. The gate electrode buffer layer, can facilitate compatibility with current CMOS processes. For example, the buffer layer can be used to prevent implants from punching through the gate. Typically, the gate electrode buffer layer is about 400-800 Å thick. Other thicknesses are also useful.

A premetal dielectric (PMD) layer (not shown) is provided over the substrate, separating the substrate and transistor from a metal level. The PMD layer comprises, for example, silicon oxide. Other types of dielectric materials are also useful. Via plugs are provided on the PMD layer which are coupled to metal lines of a metal layer over the PMD layer. The plugs and metal lines form interconnections as desired.

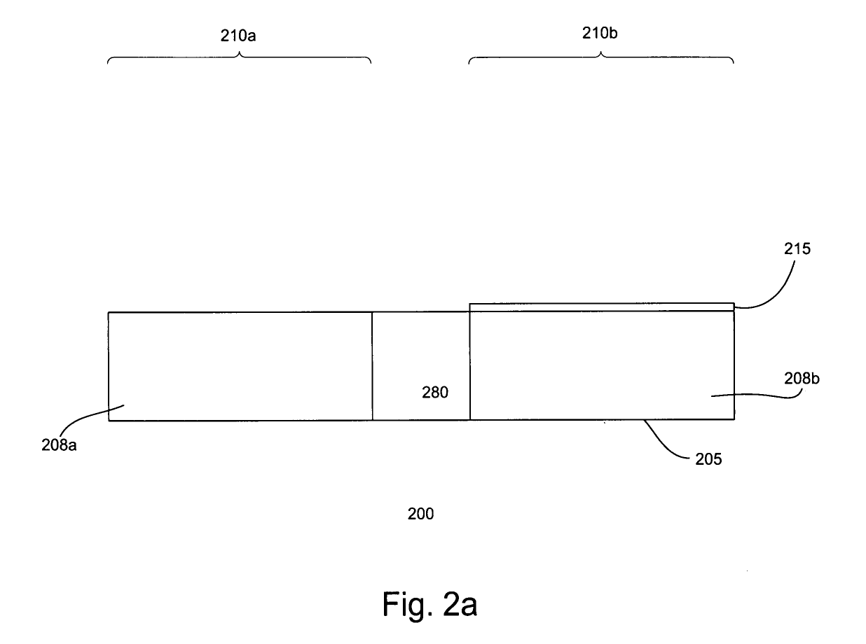

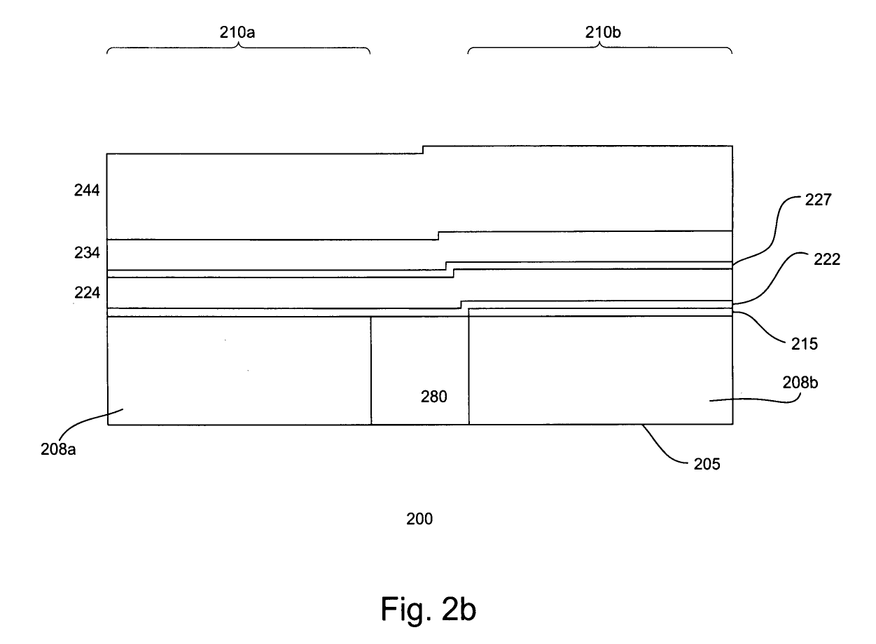

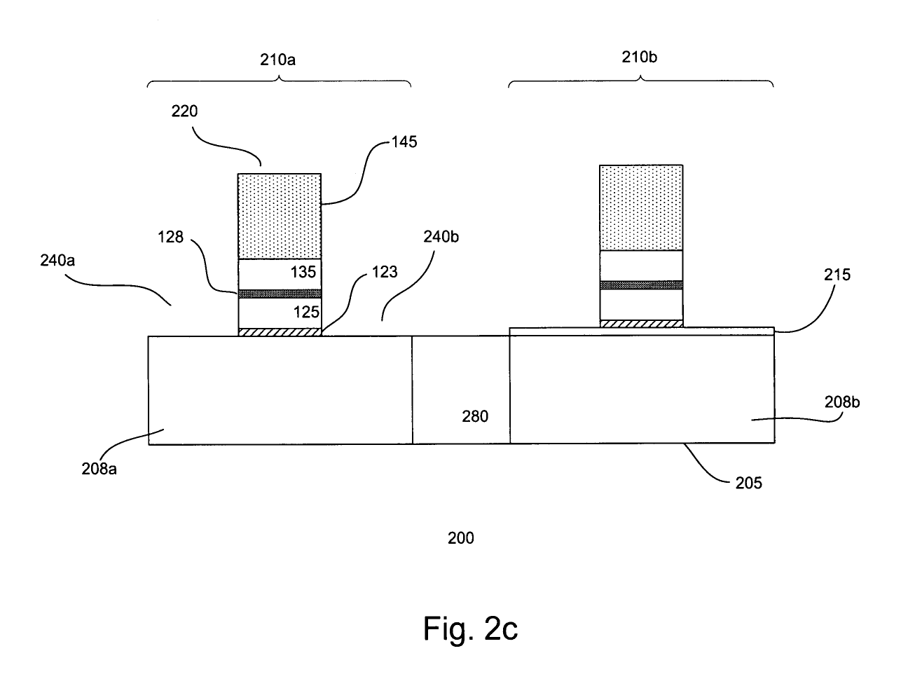

FIGS. 2a-c show cross-sectional views of an embodiment of a process for forming an IC 200. Referring to FIG. 2a, a substrate 205 is provided. The substrate can comprise a silicon substrate, such as a lightly p-type doped substrate. Other types of substrates, including silicon-on-insulator (SOI), are also useful. The substrate is prepared with first and second active regions 210a-b. The active regions comprise a heavily doped regions 208a-b with dopants of a first and a second polarity type. In one embodiment, the first active region comprises a doped well of a second polarity type and the second active region comprises a doped well of a first polarity type. The first polarity type, for example, comprises n-type and the second polarity type comprises p-type. For example, the first active region has a p-type doped well; the second active region has a n-type doped well. P-type dopants can include boron (B), aluminum or a combination thereof while n-type dopants can include phosphorus (P), arsenic (As), antimony (Sb) or a combination thereof. To form the active regions, conventional ion implantation techniques, such as implantation with a mask can be used. Generally, the first and second types of active regions are formed in separate processes. Other techniques for forming the active regions are also useful.

The substrate is also prepared with isolation regions 280 to separate the active regions from each other and other active device regions. In one embodiment, the isolation regions comprise STIs. Various conventional processes can be employed to form the STI regions. For example, the substrate can be etched using conventional etch and mask techniques to form trenches which are then filled with dielectric material such as silicon oxide. Chemical mechanical polishing (CMP) can be performed to remove excess oxide and provide a planar substrate top surface. The STI regions can be formed, for example, prior to or after the formation of the doped wells. Other processes or materials can also be used to form the STIs.

In one embodiment, a semiconductor layer 215 is formed on the surface of the substrate in the second active region. The semiconductor layer serves to adjust the threshold voltage of a transistor formed in the second active region. In one embodiment, the semiconductor layer adjusts a pFET formed in the second active region. The semiconductor layer comprises, for example, SiGe. The semiconductor layer can be formed by epitaxial growth. Other materials or deposition techniques are also useful. The thickness of the semiconductor layer can be about 20-200 Å. Other thicknesses are also useful. As shown in FIG. 2a, the semiconductor layer is elevated above the substrate surface. Providing a semiconductor layer which is coplanar with the substrate is also useful.

In one embodiment, the semiconductor layer comprises a doped semiconductor layer to counter the impact of the subsequently formed GTVA layer to produce the desired gate threshold voltage for the transistor in the second active region. The semiconductor layer, in one embodiment, comprises p-type dopants such as B. Other types of dopants are also useful. The semiconductor layer, in one embodiment, comprises a Ge concentration of about 10-50% and B concentration of about 1e19-1e21 atoms/cm³. Providing other B and Ge concentrations may also be useful. The dopants can be provided by an in-situ process. Other techniques for doping the semiconductor layer are also useful. Alternatively, the surface of the substrate in the second active region can be doped to achieve the desired gate threshold voltage for the transistor therein.

In FIG. 2b, various layers of the gate stack are formed on the substrate. In one embodiment, a buffer layer 222 is formed on the substrate. The buffer layer relieves stress and facilitates adhesion of subsequent layers. In one embodiment, the buffer layer comprises a dielectric layer. For example, the buffer layer comprises silicon oxide. Other types of dielectric materials are also useful. The buffer layer, in one embodiment, is formed by thermal oxidation. Other techniques are also useful. The buffer layer is about 20-80 Å thick.

A gate dielectric layer 224 is formed over the buffer layer. The gate dielectric layer, in one embodiment, comprises a high-k dielectric layer. The thickness of the high-k dielectric layer is about 10-40 Å. In one embodiment, the high-k dielectric layer comprises HfO₂ formed by chemical vapor deposition (CVD). Other types of high-k materials or deposition techniques are also useful. Above the high-k dielectric layer is formed a GTVA layer 227 which tunes the gate threshold voltage of the n-type transistor in the first active region.

A metal gate electrode layer 234 is deposited on the GTVA layer. The metal gate electrode layer comprises, in one embodiment, TiN. Other types of gate electrode materials are also useful. Typically, the thickness of the gate electrode layer is about 50-50 Å. Other thicknesses are also useful. Conventional techniques, such as physical vapor deposition (PVD) or atomic vapor deposition (ALD), can be used to form the metal gate layer. Other techniques are also useful.

Optionally, a gate electrode buffer layer 244 can be deposited over the metal gate layer. The gate electrode buffer layer comprises, in one embodiment, doped or undoped polysilicon. The polysilicon can be formed as an amorphous or non-amorphous layer. Various techniques, such as CVD, can be employed to form the buffer layer. The gate electrode buffer layer facilitates compatibility with conventional CMOS processes.

Referring to FIG. 2c, the various gate stack layers are patterned to form gate stacks 220 in the first and second active regions. Various techniques, such as mask and etch, can be used to form the gate stacks. For example, a photoresist layer is formed over the gate stack layers and patterned, exposing portions of the gate stack layers. An anisotropic etch, such as a reactive ion etch (RIE), is performed to remove exposed portions of the gate stack layers to form the gate stacks with layers the same as those already discussed in FIG. 1.

After the gate stacks are formed, the process continues to form the transistors. For example, spacers (not shown) and source/drain diffusion regions 240a-b are formed. Metal silicide contacts (not shown) can be provided on the surface of the diffusion regions and gate stack. The process continues to complete forming the IC. For example, the process continues by forming dielectric layers, interconnections, final passivation, dicing, and packaging.

By doping the channel of the p-type transistor, the GTVA layer can remain over both transistors while achieving symmetrical gate threshold voltages for both the p-type and n-type transistors. This advantageously avoids necessary process steps to remove the GTVA layer over the p-type transistor, simplifying processing and reducing costs.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. An integrated circuit (IC) comprising:
a substrate including first and second active regions;
a first transistor of a first type in the first active region;
a second transistor of a second type in the second active region;
first and second gate threshold voltage adjusting (GTVA) layers contacting first and second gate dielectric layers of the first and second transistors, wherein the first GTVA layer tunes a gate threshold voltage of the first transistor; and
wherein a channel of the second transistor comprises dopants to tune the gate threshold voltage of the second transistor.

2. The IC of claim 1 wherein the first type transistor comprises a n type transistor and the second type transistor comprises a p type transistor.

3. The IC of claim 2 wherein the transistors comprise metal gate electrodes.

4. The IC of claim 2 comprises a dielectric buffer layer in between the gate dielectric layers and the substrate.

5. The IC of claim 2 wherein the gate dielectric layers comprise high-k dielectric materials.

6. The IC of claim 2 comprises a gate electrode buffer layer over metal gate electrodes of the transistors.

7. The IC of claim 2 wherein the GTVA layers are disposed above, below or a combination thereof the gate dielectric layers.

8. The IC of claim 2 wherein the GTVA layer comprises lanthanum oxide (LaO).

9. The IC of claim 1 wherein the transistors comprise metal gate electrodes.

10. The IC of claim 1 comprises a dielectric buffer layer in between the gate dielectric layers and the substrate.

11. The IC of claim 1 wherein the gate dielectric layers comprise high-k dielectric materials.

12. The IC of claim 1 comprises a gate electrode buffer layer over metal gate electrodes of the transistors.

13. The IC of claim 1 wherein the GTVA layers are disposed above, below or a combination thereof the gate dielectric layers.

14. The IC of claim 1 wherein the GTVA layer comprises lanthanum oxide (LaO).

15. The IC of claim 1 wherein the channel of the second transistor comprises p type dopants.

16. The IC of claim 1 comprises a semiconductor layer on the substrate in the second active region to form the channel of the second transistor.

17. The IC of claim 16 wherein the semiconductor layer comprises doped SiGe.

18. The IC of claim 16 wherein the semiconductor layer comprises p-doped SiGe.

19. A method of forming an IC comprising:
providing a substrate prepared with first and second active regions, wherein a channel region of the second active region comprises a doped channel region;
forming a first transistor of a first type in the first active region; and
forming a second transistor of a second type in the second active region,
wherein first and second transistors include a GTVA adjacent to first and second gate dielectric layers of the first and second transistors, wherein the GTVA layer tunes a gate threshold voltage of the first transistor, and
wherein the second transistor includes a doped channel region to tune a gate threshold voltage of the second transistor.

20. A method of forming a semiconductor device comprising:
providing a substrate prepared with first and second active regions, wherein a channel region of the second active region comprises a doped channel region;
forming a first transistor of a first type in the first active region; and
forming a second transistor of a second type in the second active region,
wherein first and second transistors include a GTVA adjacent to first and second gate dielectric layers of the first and second transistors, wherein the GTVA layer tunes a gate threshold voltage of the first transistor, and
wherein the second transistor includes a doped channel region comprising a doped semiconductor layer to tune a gate threshold voltage of the second transistor.
